(19) United States
(12) Patent Application Publication
(10) Pub. No.: US 2025/0088032 A1
(43) Pub. Date: Mar. 13, 2025

(54) WIRELESS CHARGING MODULE

(71) Applicant: CYNTEC CO., LTD., Hsin-chu (TW)

(72) Inventors: KUAN-YU CHIU, Hsin-chu (TW); YEN-MING LIU, Hsin-chu (TW); CHIEN-HUI CHEN, Hsin-chu (TW); YUNG-YU CHANG, Hsin-chu (TW)

(21) Appl. No.: 18/463,890

(22) Filed: Sep. 8, 2023

(51) Int. Cl. H02J 50/10; H02J 7/00; H02J 50/40; H02J 50/70; H05K 7/20

(52) U.S. Cl. CPC H02J 50/10; H02J 7/0042; H02J 50/402; H02J 50/70; H05K 7/20145; H05K 7/20909; H05K 7/20945

(57) ABSTRACT

A wireless charging module includes a module case, a fan, a coil assembly and a circuit board. The module case defines a first cavity and a second cavity and has a first side and a second side opposite to the first side. The second side defines an air outlet. The fan is disposed at the first side of the module case and configured to form an airflow S. The coil assembly is disposed in the first cavity, so that a first air channel is formed for the airflow S to pass through a first surface of the coil assembly. The circuit board is disposed in the second cavity and configured to form a second air channel allowing the airflow S to pass through a first surface of the circuit board and a third air channel allowing the airflow S to pass through a second surface of the circuit board. The airflow S passes through the first air channel, the second air channel and the third air channel and flows out of the wireless charging module from the air outlet.

### BACKGROUND OF THE INVENTION

### Field of the Invention

The present invention relates to a charging module for charging an electronic device, in particular to a wireless charging module for charging an electronic device.

### Description of the Related Art

With the proliferation of consumer products that support wireless charging, the demand for wireless charging modules that support high wattage (e.g., >15 W) and rapid charging in automotive products is also increasing. Therefore, the market has a strong demand for the wireless charging module that can increase the chargeable area (active area) and heat dissipation effect during high wattage charging.

Typically, operating temperature is the main key factor affecting the lifetime of electronic components. Thermal simulation of existing wireless charging modules shows that heat is concentrated in specific hot spots, which can negatively affect the lifetime of electronic components and can lead to a drop in charging power. For example, coils, magnetic cores (Ferrite), electronic components, etc., may generate high heat due to energy loss, which affects the reliability and lifetime of the components.

### BRIEF SUMMARY OF THE INVENTION

An objective of an embodiment of the present invention is to provide a wireless charging module for charging an electronic device. An object of another embodiment of the present invention is to provide a wireless charging module, which is used for charging an electronic device and includes a first air channel, a second air channel and a third air channel for dissipating the heat of components of the wireless charging module.

According to an embodiment of the present invention, a wireless charging module is provided which includes a module case, at least one fan, a coil assembly and a circuit board. The module case defines a first cavity and a second cavity, and has a first side and a second side opposite to the first side. The second side defines an air outlet. The fan is disposed at the first side of the module case and configured to form an airflow. The coil assembly is disposed in the first cavity, and is configured to generate electromagnetic induction and define a first air channel for the airflow to pass through a first surface of the coil assembly. The circuit board is disposed in the second cavity and is configured to define a second air channel allowing the airflow to pass through a first surface of the circuit board and a third air channel allowing the airflow to pass through a second surface of the circuit board. The airflow passes through the first air channel, the second air channel and the third air channel, and flows out of the wireless charging module from the air outlet.

In one embodiment, the second air channel is disposed between the first air channel and the third air channel.

In one embodiment, the circuit board includes at least one first electronic component and at least one second electronic component. The amount of heat generated by the at least one first electronic component is greater than the amount of heat generated by the at least one second electronic component. The position of the at least one first electronic component on the circuit board is closer to the center of the circuit board than the position of the at least one second electronic component.

In one embodiment, the module case includes an upper cover, a case body and a lower cover. The case body has a middle partition plate. The first air channel is formed between the middle partition plate and the upper cover. The second air channel is formed between the middle partition plate and the circuit board, and the third air channel is formed between the circuit board and the lower cover.

In one embodiment, distance between the middle partition plate and the circuit board is smaller than distance between the circuit board and the lower cover.

In one embodiment, the wireless charging module further includes a ferrite element disposed below the coil assembly. The coil assembly and the ferrite element are closely bonded to the middle partition plate of the module case.

In one embodiment, the coil assembly includes a first coil, a second coil and a third coil. A left side of the first coil covers a right side of the second coil, and a left side of the second coil covers a right side of the third coil. In one embodiment, the first coil, the second coil and the third coil may be windings made of single or multiple enameled twisted wires.

In one embodiment, blades of the fan are made of polymer or metal, and rotating speed of the fan is adjusted by pulse-width modulation within a specific range, so as to control noise generated by the wireless charging module within a certain range.

In one embodiment, the upper cover is an EMI board. The lower cover is a metal plate. The module case further includes a third side and a fourth side. The third side is opposite to the fourth side, and both the third side and the fourth side extend between the first side and the second side.

In one embodiment, the wire material of the winding includes a self-adhesive wire with a self-adhesive layer. In one embodiment, the material of the ferrite element may include at least one magnetic material selected from a group consisting of manganese zinc ferrite, nickel zinc ferrite, ferrite and nanocrystalline, and the ferrite element is formed by sintering or ceramic injection molding.

In one embodiment, the material of the module case is made of a metal or a plastic material, and is formed by way of stamping, die-casting, injection molding, or processing using a processing machine. In one embodiment, the at least one first electronic component and at least one second electronic component may include at least one of NFC device, NTC thermistor, 5G antenna, FAKRA connector and EMI shielding patterns.

According to an embodiment of the present invention, since the wireless charging module includes the first air channel, the second air channel and the third air channel, the heat generated by the components of the wireless charging module can be dissipated more efficiently, and these air channels can form an effective spatial convection that can effectively dissipate heat.

### BRIEF DESCRIPTION OF THE SEVERAL VIEWS OF THE DRAWINGS

FIG. 1 is an exploded view of a wireless charging module according to an embodiment of the present invention.

FIG. 2 is a perspective view of a wireless charging module according to an embodiment of the present invention.

FIG. 3 is a perspective view of a side section of a wireless charging module according to an embodiment of the present invention.

FIG. 4 is a comparison table of thermal simulation temperatures of different components obtained by wireless charging simulation of an electronic device using a wireless charging module with a fan according to an embodiment of the present invention and a wireless charging module without a fan.

FIG. 5 is a comparison table of thermal simulation temperatures of different positions on the outside surface of a wireless charging module obtained by wireless charging simulation of an electronic device using the wireless charging module with a fan according to an embodiment of the present invention and the wireless charging module without a fan.

FIG. 6A shows a simulation diagram of the flow field of a wireless charging module according to an embodiment of the present invention.

FIG. 6B shows a table of the volume of airflows in each air channel of a wireless charging module according to an embodiment of the present invention.

### DETAILED DESCRIPTION OF THE INVENTION

In the following, the details will be described with reference to the accompanying drawings. The contents in the accompanying drawings also constitute a part of the detailed description of the specification, and are illustrated in a specific description manner that can implement the embodiment. The following embodiments have described sufficient details to enable those skilled in the art to implement the technology. Of course, other embodiments can also be adopted, or any structural, logical, and electrical modifications can be made without departing from the embodiments described in this disclosure. Therefore, the following detailed description should not be regarded as a limitation. On the contrary, the embodiments contained therein will be defined by the scope of the claims. The drawings illustrating the various embodiments of the device are not drawn to scale, and in particular, certain dimensions are for clarity of presentation and are shown exaggeratedly in the drawings.

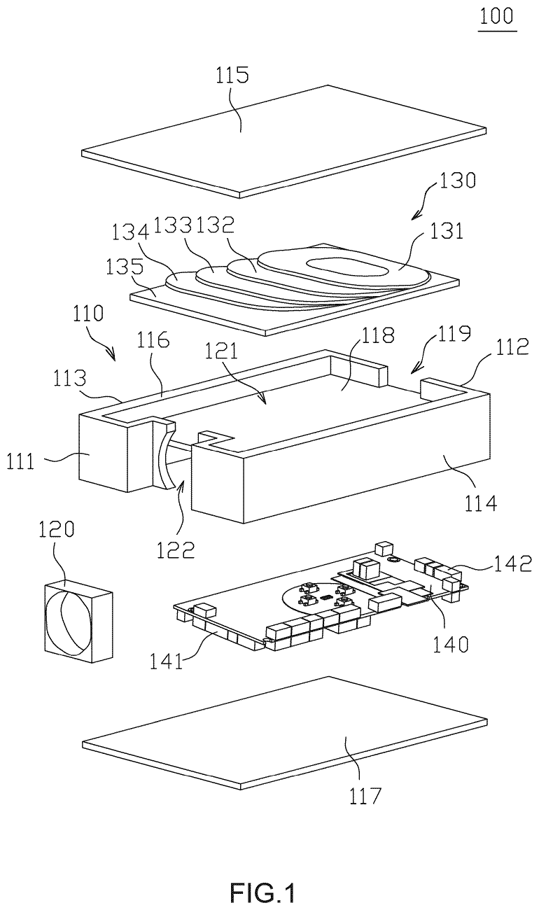

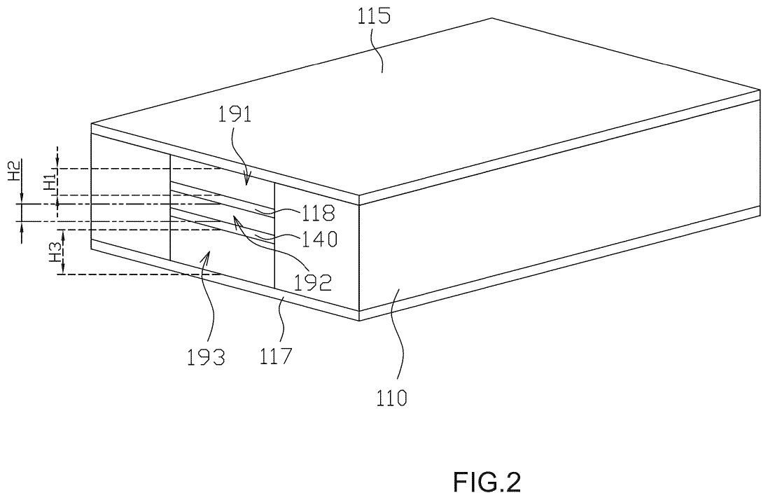

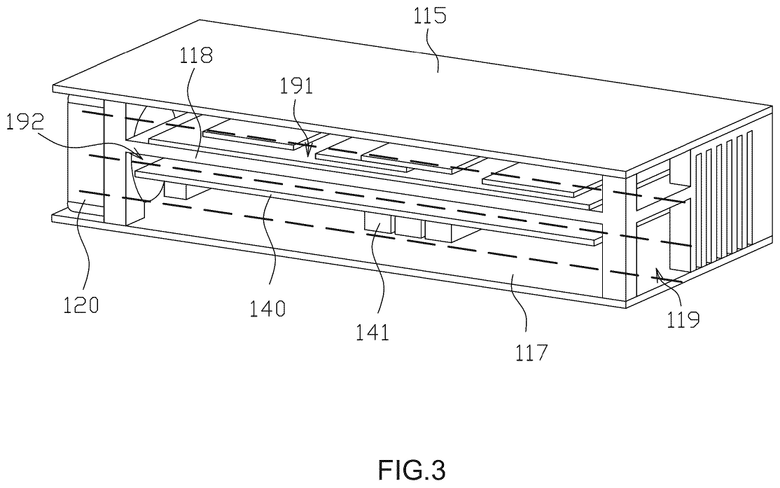

FIG. 1 is an exploded view of a wireless charging module according to an embodiment of the present invention. FIG. 2 is a perspective view of a wireless charging module according to an embodiment of the present invention. FIG. 3 is a perspective view of a side section of a wireless charging module according to an embodiment of the present invention.

According to an embodiment of the present invention, as shown in FIGS. 1 to 3, the wireless charging module 100 includes: a module case 110, at least one fan 120, a coil assembly 130 and a circuit board 140. The module case 110 defines a first cavity 121 and a second cavity 122, and has a first side 111 and a second side 112 opposite to the first side 111. The second side 112 defines an air outlet 119. In this embodiment, the number of fans 120 is one which is described as an example. The fan 120 is disposed at the first side 111 of the module case 110 to form an airflow S. The circuit board 140 may be a printed circuit board assembly (PCBA). The printed circuit board assembly includes main electronic components of the wireless charging module 100, and the heat generated by the electronic components is mainly dissipated to the outside of the wireless charging module 100 by heat convection.

The coil assembly 130 is disposed in the first cavity 121 and is configured to generate electromagnetic induction and define a first air channel 191 for the airflow S to pass through a first surface of the coil assembly 130. A second surface of the coil assembly 130 faces the module case 110 to define a surface of the first cavity 121. As shown in FIGS. 2 to 3, the circuit board 140 is disposed in the second cavity 122 and configured to define a second air channel 192 for the airflow S to pass through the first surface of the circuit board 140, and a third air channel 193 for the airflow S to pass through the second surface of the circuit board 140. The airflow S passes through the first air channel 191, the second air channel 192 and the third air channel 193, and flows out of the wireless charging module 100 from the air outlet 119. In this embodiment, the second air channel 192 is located between the first air channel 191 and the third air channel 193. Further, in the embodiment of FIG. 2, the first surface of the circuit board 140 is the top surface, and the second surface of the circuit board 140 is the bottom surface.

In one embodiment, as shown in FIG. 1, the module case 110 includes a top cover 115, a case body 116 and a bottom cover 117. The case body 116 has a middle partition plate 118. The first air channel 191 is formed between the middle partition plate 118 and the top cover 115. The second air channel 192 is formed between the middle partition plate 118 and the circuit board 140. The third air channel 193 is formed between the circuit board 140 and the bottom cover 117. The present invention does not limit the manufacturing method and material of the module case 110. In one embodiment, the material of the module case 110 may be metal or plastic materials. In one embodiment, the module case 110 may be formed by ways of stamping, die-casting, injection molding, or processing using a processing machine.

The second surface of the coil assembly 130 faces the middle partition plate 118, and the airflow S passes through the first surface (the top surface in the embodiment of FIG. 1) of the coil assembly 130. In one embodiment, the wireless charging module 100 further includes a ferrite element 132. The ferrite element 132 is disposed below the coil assembly 130. The coil assembly 130 and the ferrite element 132 are bonded as closely as possible to the middle partition plate 118 of the module case 110. In one embodiment, the material of the ferrite element 132 includes magnetic material of manganese zinc ferrite, nickel zinc ferrite, ferrite or nanocrystalline, and the ferrite element 132 is formed by ways of sintering or ceramic injection molding.

In one embodiment, the top cover 115 may be an EMI board (Electromagnetic interference board), and the EMI board is a circuit board that is used to reduce electromagnetic interference (EMI) generated by electronic equipment and to resist external electromagnetic interference. The bottom cover 117 is a metal plate for increasing the cooling effect. The module case 110 further has a third side 113 and a fourth side 114. The third side 113 is opposite to the fourth side 114, and the third side 113 and the fourth side 114 both extend from the first side 111 to the second side 112. In one embodiment, neither the third side 113 nor the fourth side 114 defines a through hole. Since the fan 120 is disposed on the first side 111 of the module case 110, and the second side 112 defines an air outlet 119, the airflow S flows into the wireless charging module 100 from the first side 111 and then flows out from the air outlet 119 of the second side 112, so as to form a cooling airflow field.

In one embodiment, the coil assembly 130 includes a first coil 131, a second coil 132 and a third coil 133. According to the viewing angle shown in FIG. 1, the left side of the first coil 131 covers the right side of the second coil 132, and the left side of the second coil 132 covers the right side of the third coil 133. In one embodiment, the coil assembly 130 may further include a fourth coil 134, and the left side of the third coil 133 covers the right side of the fourth coil 134. In such a configuration, the centers of the coils are not stacked on top of each other but are placed side by side, thereby making the coupling coefficient more uniform, reducing coupling blind spots, and increasing the chargeable area (or active area). In one embodiment, the coils are windings made of single or multiple enameled twisted wires. In one embodiment, the wire of the windings may include a self-adhesive wire having a self-adhesive layer.

In one embodiment, the circuit board 140 of the module case 110 includes at least one first electronic component 141 and at least one second electronic component 142. The amount of heat generated by the at least one first electronic component 141 is greater than the amount of heat generated by the at least one second electronic component 142. The position of the at least one first electronic component 141 on the circuit board is closer to the center of the circuit board 140 than the position of the at least one second electronic component 142. For example, the at least one first electronic component 141 may be or include a microprocessor or a choke. In one embodiment, the at least one first electronic component 141 and at least one second electronic component 142 include at least one of NFC device (Near Field Communication Device), NTC (Negative Temperature Coefficient) thermistor, 5G antenna, FAKRA connector and EMI shielding patterns. NFC device is a short-range high-frequency wireless communication device. The resistance value of NTC thermistor will decrease as the temperature rises, which can be used for temperature sensing, over-current protection or power supply stabilization, etc.

In one embodiment, the second surface of the circuit board 140 is closer to the external environment than the first surface thereof. Therefore, the first electronic component 141, such as a microprocessor or a choke, may be disposed on the second surface of the circuit board 140.

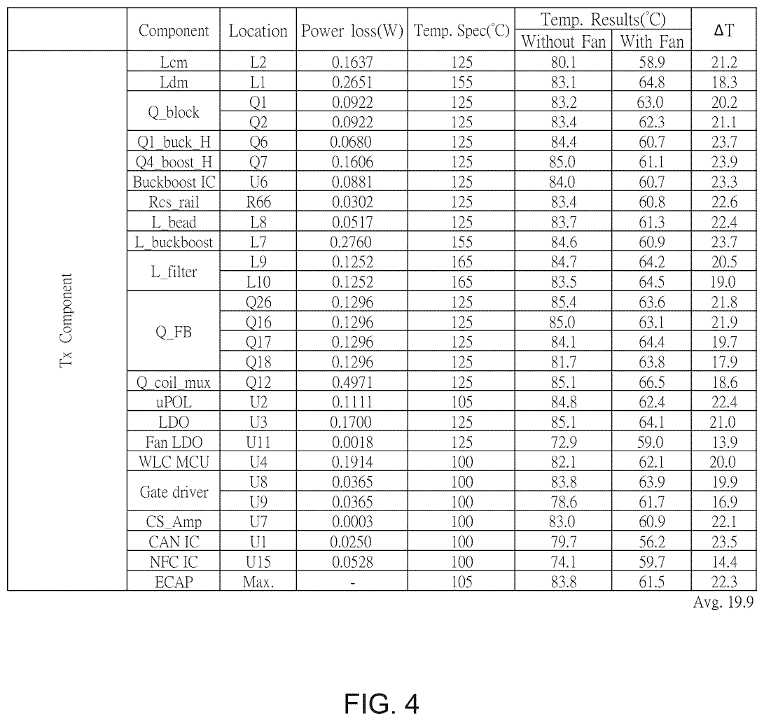

FIG. 4 is a comparison table of thermal simulation temperatures of different components obtained by wireless charging simulation of an electronic device using a wireless charging module with a fan according to an embodiment of the present invention and a wireless charging module without a fan. As shown in FIG. 4, the wireless charging module 100 using the fan 120 to form three airflows according to an embodiment of the present invention can effectively reduce the temperature of various parts of the printed circuit board assembly (PCBA) by nearly 20° C. on average.

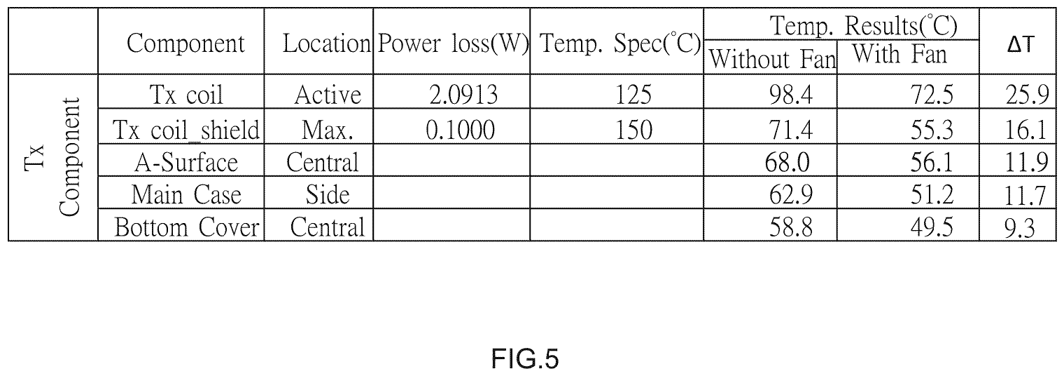

FIG. 5 is a comparison table of thermal simulation temperatures of different positions on the outside surface of a wireless charging module obtained by wireless charging simulation of an electronic device using the wireless charging module with a fan according to an embodiment of the present invention and the wireless charging module without a fan. In FIG. 5, Tx coil refers to the coil assembly 130, Tx coil shield refers to the top cover 115 of the EMI board, A-Surface refers to the center of the outer surface of the top cover 115, Main Case refers to the case body 116, Bottom Cover refers to the bottom cover 117. As shown in FIG. 5, the wireless charging module 100 using the fan 120 to form three airflows according to an embodiment of the present invention can effectively reduce the temperature of the coil assembly 130 by nearly 26° C. and reduce the temperature at the center of the outer surface of the top cover 115 by nearly 12° C.

As shown in FIGS. 4 and 5, the wireless charging module 100 includes a first air channel 191, a second air channel 192 and a third air channel 193, which can more efficiently dissipate heat from the components of the wireless charging module 100. These air channels can form effective spatial convection, and can effectively dissipate heat.

In one embodiment, blades of the fan 120 are made of polymer or metal, and rotating speed of the fan 120 is adjusted by pulse-width modulation within a specific range, so as to control noise generated by the wireless charging module 100 within a certain range. In addition, the rotating speed of the fan 120 can be adjustable or non-adjustable. In one embodiment, as shown in FIG. 2, distance H2 between the middle partition plate 118 and the circuit board 140 is smaller than distance H3 between the circuit board 140 and the bottom cover 117. Accordingly, the volume of the airflow S in the third air channel 193 can be increased.

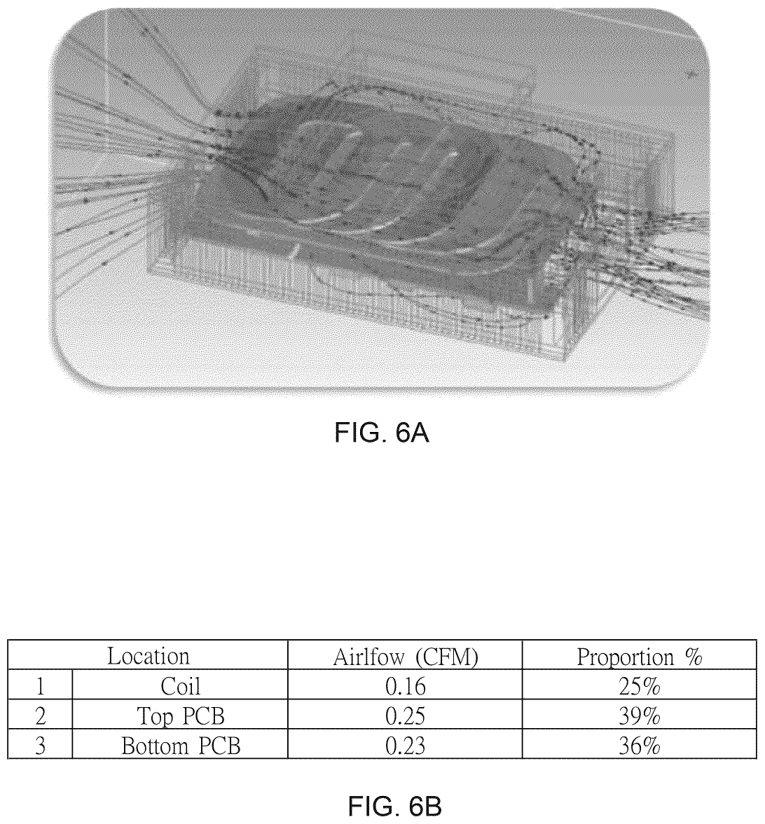

FIG. 6A shows a simulation diagram of the flow field of a wireless charging module according to an embodiment of the present invention. FIG. 6B shows a table of the volume of airflows in each air channel of a wireless charging module according to an embodiment of the present invention. Since the wireless charging module 100 usually has a size limitation, in the embodiments shown in FIGS. 6A and 6B, a small fan 120 having a size of 25 mm*25 mm*10 mm is used as an active cooling solution, and the cooling effect is successfully achieved. In one embodiment, the middle part of the fan 120 can generate a larger airflow volume, while the outer part of the fan 120 can generate a smaller airflow volume. Therefore, by increasing the area of the entrance of the third air channel 193, the volume of the airflow S in the second air channel 192 and the third air channel 193 can be made more uniform. As shown in the table of FIG. 6B, the ratios of the volume of the airflow S in the first air channel 191, the second air channel 192 and the third air channel 193 are 25%, 39% and 36%, respectively.

In addition, please refer to the airflow field diagram in FIG. 6A. From the airflow field diagram in FIG. 6A, it can be known that the volume of the airflow S flowing through the central part of the first cavity 121 or the second cavity 122 is larger than that flowing through the corner part of the first cavity 121 or the second cavity 122. Therefore, in one embodiment, components with high heat generation such as microprocessors or chocks can be arranged near the central part of the circuit board 140 or the second cavity 122 instead of being arranged at the corner part of the circuit board 140 or the second cavity 122.

According to an embodiment of the present invention, the wireless charging module 100 is provided with a first air channel 191, a second air channel 192 and a third air channel 193. These air channels can form effective spatial convection and efficiently dissipate heat from the wireless charging module 100 that support high wattage (e.g. >15 W) and rapid charging.

The foregoing descriptions are only directed to preferred embodiments of the present invention, and all equivalent changes and modifications made in accordance with the claims of the present invention shall be deemed as falling within the scope of the present invention.

What is claimed is:

1. A wireless charging module (100), comprising:
a module case (110) defining a first cavity (121) and a second cavity (122), and having a first side (111) and a second side (112) opposite to the first side (111), wherein the second side (112) defines an air outlet (119);
a fan (120) disposed at the first side (111) of the module case (110) configured to form an airflow(S);
a coil assembly (130) disposed in the first cavity (121) and configured to generate electromagnetic induction and define a first air channel (191) for the airflow(S) to pass through a first surface of the coil assembly (130);
a circuit board (140) disposed in the second cavity (122) and configured to define a second air channel (192) allowing the airflow(S) to pass through a first surface of the circuit board (140) and a third air channel (193) allowing the airflow(S) to pass through a second surface of the circuit board (140),
wherein the airflow(S) passes through the first air channel (191), the second air channel (192) and the third air channel (193), and flows out of the wireless charging module (100) from the air outlet (119).

2. The wireless charging module (100) according to claim 1, wherein the second air channel (192) is disposed between the first air channel (191) and the third air channel (193).

3. The wireless charging module (100) according to claim 1, wherein
the circuit board (140) comprises at least one first electronic component (141) and at least one second electronic component (142),
the amount of heat generated by the at least one first electronic component (141) is greater than the amount of heat generated by the at least one second electronic component (142), and
the position of the at least one first electronic component on the circuit board is closer to the center of the circuit board than the position of the at least one second electronic component.

4. The wireless charging module (100) according to claim 1, wherein
the module case (110) comprises an upper cover (115), a case body (116) and a lower cover (117),
the case body (116) has a middle partition plate (118),
the first air channel (191) is formed between the middle partition plate (118) and the upper cover (115), the second air channel (192) is formed between the middle partition plate (118) and the circuit board (140), and the third air channel (193) is formed between the circuit board (140) and the lower cover (117).

5. The wireless charging module (100) according to claim 4, wherein
distance between the middle partition plate (118) and the circuit board (140) is smaller than distance between the circuit board (140) and the lower cover (117).

6. The wireless charging module (100) according to claim 4 further comprising:
a ferrite element (132) disposed below the coil assembly (130), wherein the coil assembly (130) and the ferrite element (132) are closely bonded to the middle partition plate (118) of the module case (110).

7. The wireless charging module (100) according to claim 1, wherein
the coil assembly (130) comprises: a first coil, a second coil and a third coil,
a left side of the first coil covers a right side of the second coil, and a left side of the second coil covers a right side of the third coil.

8. The wireless charging module (100) according to claim 1, wherein
blades of the fan (120) are made of polymer or metal, and
rotating speed of the fan (120) is adjusted by pulse-width modulation within a specific range, so as to control noise generated by the wireless charging module (100) within a certain range.

9. The wireless charging module (100) according to claim 4, wherein
the upper cover (115) is an EMI board,
the lower cover (117) is a metal plate,
the module case (110) further comprises a third side (113) and a fourth side (114),
the third side (113) is opposite to the fourth side (114), and both the third side (113) and the fourth side (114) extend between the first side (111) and the second side (112).

10. The wireless charging module (100) according to claim 7, wherein the first coil, the second coil and the third coil are windings made of single or multiple enameled twisted wires.

11. The wireless charging module (100) according to claim 12, wherein the wire material of the winding comprises a self-adhesive wire with a self-adhesive layer.

12. The wireless charging module (100) according to claim 6, wherein
the material of the ferrite element (132) comprises at least one magnetic material selected from a group consisting of manganese zinc ferrite, nickel zinc ferrite, ferrite and nanocrystalline, and
the ferrite element (132) is formed by sintering or ceramic injection molding.

13. The wireless charging module (100) according to claim 1, wherein
the material of the module case (110) is made of a metal or a plastic material, and is formed by way of stamping, die-casting, injection molding, or processing using a processing machine.

14. The wireless charging module (100) according to claim 2, wherein
the at least one first electronic component (141) and at least one second electronic component (142) comprise at least one of NFC device, NTC thermistor, 5G antenna, FAKRA connector and EMI shielding patterns.
